(19) United States
(12) Patent Application Publication
(10) Pub. No.: US 2018/0315708 A1
(43) Pub. Date: Nov. 1, 2018

(54) POWER RAIL AND MOL CONSTRUCTS FOR FDSOI

(71) Applicant: GLOBALFOUNDRIES Inc., Grand Cayman (KY)

(72) Inventors: Anurag MITTAL, San Jose, CA (US); Mahbub RASHED, Cupertino, CA (US)

(73) Assignee: GLOBALFOUNDRIES Inc., Grand Cayman (KY)

(21) Appl. No.: 15/583,449

(22) Filed: May 1, 2017

(51) Int. Cl. H01L 23/528; H01L 29/45; H01L 29/08; H01L 27/12; H01L 23/532; H01L 23/522

(52) U.S. Cl. CPC H01L 23/5286; H01L 29/45; H01L 29/0847; H01L 23/5226; H01L 23/53257; H01L 23/53209; H01L 27/1203

(57) ABSTRACT

An electrical connection is provided between a source/drain of a planar transistor and a local interconnect or first metallization layer power rail, includes a first contact area electrically coupled to the source/drain, a second contact area electrically coupled to the first contact area and a gate of the transistor, and a V₀ electrically coupled to the local interconnect or first metallization layer power rail. Trench silicide is absent from the transistor. A contact area-based power rail spine is also provided including a first contact area, a second contact area and adjacent V₀ bi-directional staple both over and electrically coupled to the first contact area, and a V₀ over and electrically coupled to the second contact area and the V₀ bi-directional staple. The power rail spine may be included in a semiconductor structure including planar transistors, in which the first contact area and second contact area are electrically coupled to a source/drain of a transistor, a via-type gate contact is also electrically coupled to the second contact area under the V₀. The first metallization layer and/or the contact areas may be made of a non-copper heavy metal with a minimum area less than that of copper.

### BACKGROUND

### Technical Field

The present invention generally relates to the design of interconnect structures for semiconductor devices. More particularly, the present invention relates to a power rail construct and related MOL constructs for gate-first semiconductor device technologies.

### Background Information

CMOS bulk and FinFET technologies are running into design blocks and reliability issues with trench silicide use (e.g., V₀ shorting to the trench silicide) as semiconductor devices continue to scale downward, for example, below 14 nm, so the industry is moving toward fully-depleted silicon-on-insulator (FDSOI), a gate-first technology, as a replacement for CMOS bulk and FinFET technologies. The library cells for the design of the interconnect structures for the scaled-down devices likewise have to scale downward. However, fundamental changes to the existing power structure are needed to scale down such interconnect design.

### SUMMARY

The shortcomings of the prior art are overcome and additional advantages are provided through the provision, in one aspect, of a semiconductor structure. The semiconductor structure comprises at least one source or drain region of at least one semiconductor device, a first metallization layer of an interconnect structure for the at least one semiconductor device, at least one first contact area electrically coupled to the at least one source or drain region, at least one second contact area electrically coupled to the at least one first contact area, at least one V₀ electrically coupled to the at least one second contact area, the first metallization layer being electrically coupled to the at least one V₀, and at least one first gate and at least one second gate, the at least one first gate and the at least one second gate are metal gates. The at least one source or drain region is situated adjacent one or more of the at least one first gate and the at least one second gate, the at least one second contact area is also electrically coupled to one or more of the at least one first gate and the at least one second gate, trench silicide is absent from the semiconductor structure, and the semiconductor structure is planar.

In accordance with another aspect, a semiconductor structure is provided. The semiconductor structure comprises at least one source or drain region of at least one semiconductor device, at least one first contact area electrically coupled to the at least one source or drain region, at least one second contact area electrically coupled to the at least one first contact area, at least one V₀ bi-directional staple adjacent the at least one second contact area and electrically coupled to the at least one second contact area and the at least one first contact area, and at least one V₀ above and electrically coupled to the at least one second contact area and the at least one V₀ bi-directional staple. The semiconductor structure further comprises at least one first gate and at least one second gate, the at least one first gate and the at least one second gate are metal gates, the at least one source or drain region is situated adjacent one or more of the at least one first gate and the at least one second gate, the at least one second contact area is also electrically coupled to one or more of the at least one first gate and the at least one second gate, trench silicide is absent from the semiconductor structure, and the semiconductor structure is planar.

In accordance with yet another aspect, a semiconductor structure is provided. The semiconductor structure comprises at least one first contact area, at least one second contact area above and electrically coupled to the at least one first contact area, at least one V₀ bi-directional staple adjacent the at least one second contact area and electrically coupled to the at least one second contact area and the at least one first contact area, at least one V₀ above and electrically coupled to the at least one second contact area and the at least one V₀ bi-directional staple, and a first metallization layer power rail electrically coupled to the at least one V₀, the first metallization power rail is made of a non-copper heavy metal having a minimum area less than that of copper, and the at least one first contact area, the at least one second contact area, the at least one V₀ bi-directional staple and the at least one V₀, together serve as a power rail spine.

### BRIEF DESCRIPTION OF THE DRAWINGS

These, and other objects, features and advantages of this invention will become apparent from the following detailed description of the various aspects of the invention taken in conjunction with the accompanying drawings, in which:

FIG. 1 is a cross-sectional view of one example of an electrical construct for a semiconductor device interconnect structure, in accordance with one or more aspects of the present invention.

FIG. 2 is a cross-sectional view of one example of a semiconductor “stitch,” as part of an electrical construct for a semiconductor device interconnect, in accordance with one or more aspects of the present invention.

FIG. 3 is a top-down view of a power rail construct of an interconnect structure for semiconductor devices, in accordance with one or more aspects of the present invention.

FIG. 4 is one example of a top-down view of the effect of centering V₀ on a non-copper heavy metal power rail having a minimum area less than that of copper, on tracks and power rails of an interconnect structure, in accordance with one or more aspects of the present invention.

FIG. 5 is one example of a conventional construct for electrically connecting a source or drain to a first metallization layer of an interconnect structure for semiconductor device(s), in accordance with one or more aspects of the present invention. The connection is achieved using a trench silicide contact, a (single) contact area and V₀. The gate has a separate contact.

### DETAILED DESCRIPTION

Aspects of the present invention and certain features, advantages, and details thereof, are explained more fully below with reference to the non-limiting examples illustrated in the accompanying drawings. Descriptions of well-known materials, fabrication tools, processing techniques, etc., are omitted so as not to unnecessarily obscure the invention in detail. It should be understood, however, that the detailed description and the specific examples, while indicating aspects of the invention, are given by way of illustration only, and are not by way of limitation. Various substitutions, modifications, additions, and/or arrangements, within the spirit and/or scope of the underlying inventive concepts will be apparent to those skilled in the art from this disclosure.

Approximating language, as used herein throughout the specification and claims, may be applied to modify any quantitative representation that could permissibly vary without resulting in a change in the basic function to which it is related. Accordingly, a value modified by a term or terms, such as “about,” is not limited to the precise value specified. In some instances, the approximating language may correspond to the precision of an instrument for measuring the value.

The terminology used herein is for the purpose of describing particular examples only and is not intended to be limiting of the invention. As used herein, the singular forms “a”, “an” and “the” are intended to include the plural forms as well, unless the context clearly indicates otherwise. It will be further understood that the terms “comprise” (and any form of comprise, such as “comprises” and “comprising”), “have” (and any form of have, such as “has” and “having”), “include (and any form of include, such as “includes” and “including”), and “contain” (and any form of contain, such as “contains” and “containing”) are open-ended linking verbs. As a result, a method or device that “comprises,” “has,” “includes” or “contains” one or more steps or elements possesses those one or more steps or elements, but is not limited to possessing only those one or more steps or elements. Likewise, a step of a method or an element of a device that “comprises,” “has,” “includes” or “contains” one or more features possesses those one or more features, but is not limited to possessing only those one or more features. Furthermore, a device or structure that is configured in a certain way is configured in at least that way, but may also be configured in ways that are not listed.

As used herein, the term “connected,” when used to refer to two physical elements, means a direct connection between the two physical elements. The term “coupled,” however, can mean a direct connection or a connection through one or more intermediary elements.

As used herein, the terms “may” and “may be” indicate a possibility of an occurrence within a set of circumstances; a possession of a specified property, characteristic or function; and/or qualify another verb by expressing one or more of an ability, capability, or possibility associated with the qualified verb. Accordingly, usage of “may” and “may be” indicates that a modified term is apparently appropriate, capable, or suitable for an indicated capacity, function, or usage, while taking into account that in some circumstances the modified term may sometimes not be appropriate, capable or suitable. For example, in some circumstances, an event or capacity can be expected, while in other circumstances the event or capacity cannot occur—this distinction is captured by the terms “may” and “may be.”

As used herein, unless otherwise specified, the term “about” used with a value, such as measurement, size, etc., means a possible variation of plus or minus five percent of the value. Also, where used, the term “low-k dielectric” refers to a dielectric with a dielectric constant k<3.9.

As used herein, “about” or “approximately” indicate +/−5% of the value(s) stated.

Spatially relative terms, such as “beneath,” “below,” “lower,” “above,” “upper,” and the like, may be used herein for ease of description to describe one element's or feature's relationship to another element(s) or feature(s) as illustrated in the figures. It will be understood that the spatially relative terms are intended to encompass different orientations of the device in use or operation, in addition to the orientation depicted in the figures. For example, if the device in the figures is turned over, elements described as “below” or “beneath” other elements or features would then be oriented “above” or “over” the other elements or features. Thus, the exemplary term “below” may encompass both an orientation of above and below. The device may be otherwise oriented (e.g., rotated 90 degrees or at other orientations) and the spatially relative descriptors used herein should be interpreted accordingly. When the phrase “at least one of” is applied to a list, it is being applied to the entire list, and not to the individual members of the list.

Reference is made below to the drawings, which may not be drawn to scale for ease of understanding, wherein the same reference numbers may be used throughout different figures to designate the same or similar components.

The present invention moves semiconductor device interconnect power design forward by providing a power rail construct that includes V₀, (i.e., a via-filled contact to a first metallization layer of an interconnect structure), and breaks the contact area (CA) into a first contact area and a second contact area for middle-of-the-line (MOL) gate-first technology (e.g., FDSOI devices). Preferably, the power rails and contact areas are made of a non-copper heavy metal having a minimum area less than that of copper (e.g., tungsten and/or cobalt) providing a thinner power rail, and no barrier material is needed for smaller geometries, such a power rail construct being useful for semiconductor devices, such as, for example, logic, memory and analog applications. Placement of V₀ along a center line of the non-copper power rail enables shrinking the standard cell library below 7.5 tracks. A V₀ staple in the power rail spine replaces a conventional zig-zag design. Also provided is to combine the second contact area with CB (gate contact) to save an additional mask. Further provided is a CA-based power rail spine.

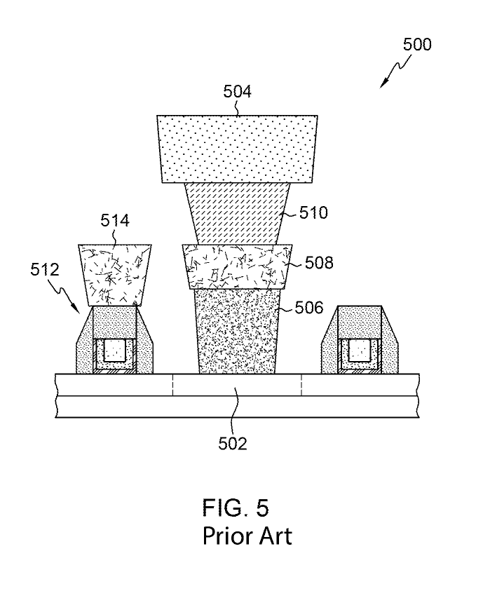

FIG. 5 is one example of a conventional construct 500 for electrically connecting a source or drain 502 to a first metallization layer 504 of an interconnect structure for semiconductor device(s), in accordance with one or more aspects of the present invention. The connection is achieved using a trench silicide contact 506, a (single) contact area 508 and V₀ 510. Gate 512 has a separate contact 514.

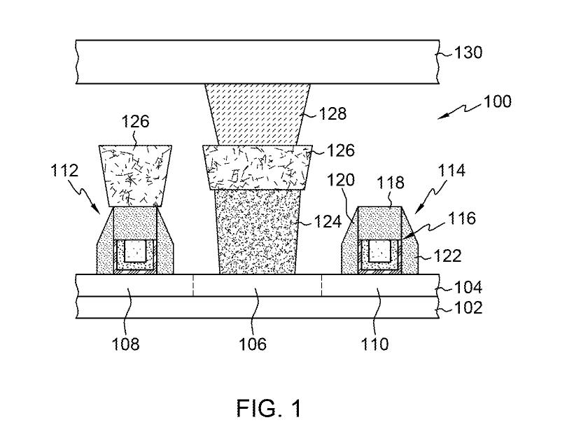

FIG. 1 is a cross-sectional view of one example of a semiconductor structure 100, in accordance with one or more aspects of the present invention. The semiconductor structure includes, for example, a substrate 102 with active area 104 thereover. The active area includes, for example, a source or drain 106 (hereinafter, “source/drain”) between channels 108 and 110. Over the channels are metal gate structures 112 and 114, respectively. Each metal gate structure includes, using metal gate structure 114 as an example, a metal gate electrode 116, which may include, for example, one or more outer work-function layers and inner metal, a gate cap 118 and spacers 120 and 122. Over the source/drain is a first contact area 124, which may be, for example, square or rectangular shaped, and over both metal gate structure 112 and the first contact area is a second contact area 126, shown here with two portions electrically coupled together, but could instead be a single piece. Over the second contact area above the first contact area is V₀ 128 to a top layer 130, which may be, for example, a local interconnect or a first metallization layer power rail.

As shown in FIG. 1, the present invention provides a two-layer contact area solution; a first contact area and a second contact area. The first contact area can be, for example, square or rectangular, and, unlike trench silicide, need not be extended across the entire source/drain. The second contact area is used for gate contacts as well as for source and drain connections to the first contact area, instead of two different contacts. In this design, the second contact area lands on the first contact area, enabling a power rail without impacting pin access. In addition, the second contact area can employ a three-dimensional connection (i.e., sidewall and top-down connections) in order to ensure a dense library and a bi-directional connection. Although only a single set of constituent structures is shown in FIG. 1 (here, for a transistor), it will be understood that in practice, there would be many more separated by isolation regions. Note that the electrical path from the source or drain to the top layer is direct, and does not cross any isolation regions.

The semiconductor structure of FIG. 1 may be conventionally fabricated, for example, using known processes and techniques. However, although only a portion is shown for simplicity, it will be understood that, in practice, many such structures are typically included on the same substrate.

In one example, substrate 102 may include any silicon-containing substrate including, but not limited to, silicon (Si), single crystal silicon, polycrystalline Si, amorphous Si, silicon-on-nothing (SON), silicon-on-insulator (SOI) or silicon-on-replacement insulator (SRI) or silicon germanium substrates and the like. Substrate 102 may in addition or instead include various isolations, dopings and/or device features. The substrate may include other suitable elementary semiconductors, such as, for example, germanium (Ge) in crystal, a compound semiconductor, such as silicon carbide (SiC), gallium arsenide (GaAs), gallium phosphide (GaP), indium phosphide (InP), indium arsenide (InAs), and/or indium antimonide (InSb) or combinations thereof; an alloy semiconductor including GaAsP, AlInAs, GaInAs, GaInP, or GaInAsP or combinations thereof.

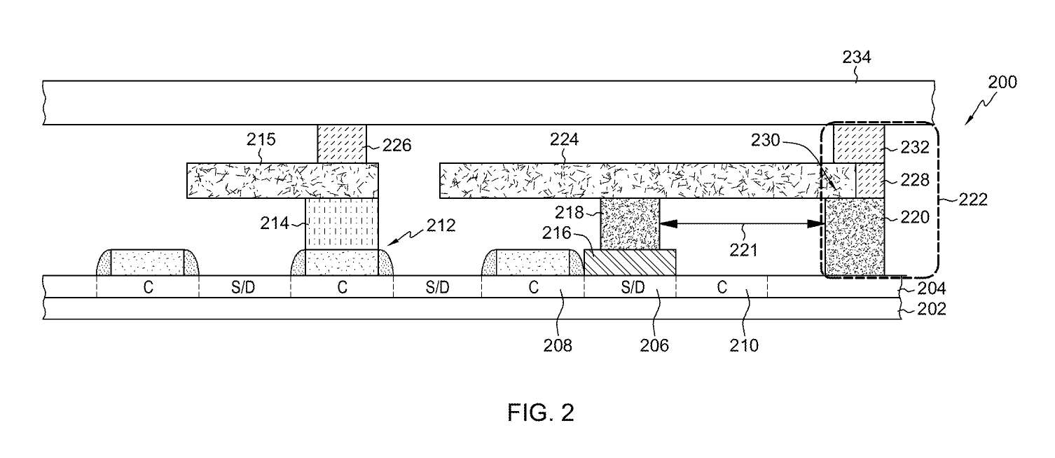

FIG. 2 is a cross-sectional view of another example of a semiconductor structure 200, in accordance with one or more aspects of the present invention. The semiconductor structure includes, for example, a substrate 202 with active area 204 thereover. The active area includes, for example, a number of source/drain's (e.g., source/drain 206) situated between channels (e.g., channels 208 and 210). Over the channels are metal gate structures (e.g., metal gate structure 212) similar to that of FIG. 1, but simplified here. In this example, metal gate structure 212 has undergone a GOP (gate open) process to form a via-type connection 214 to metal gate structure 212. Over the via-type connection is a jumper 215 to a second contact area 224, and over the jumper is a first V₀ 226. Over source/drain 206 is epitaxial semiconductor material 216 (e.g., formed using the source/drain to seed). Over the epitaxial semiconductor material is a first portion 218 of a first contact area with a second portion 220 of the first contact area situated over the active area separated by a space 221. Over the first portion of the first contact area and partially over the second portion of the first contact area is second contact area 224. Adjacent the second contact area and over part of the second portion of the first contact area is a bi-directional V₀ staple 228, which removes the need to double-pattern V₀ by randomly stapling V₀ into a power rail or other power grid, allowing for a more dense library design. Above an end portion 230 of the second contact area and the bi-directional V₀ staple is a second V₀ 232. Over the second V₀ is a layer 234, which may be part of a local interconnect or be part of a first metallization layer power rail of an interconnect structure for one or more of the semiconductor devices. Collectively, the second portion of the first contact area 220, the right end portion of the second contact area and adjacent bi-directional V₀ staple 228, along with the second V₀ 232, form a “stitch” 222, in accordance with one or more aspects of the present invention. Where, for example, layer 234 is a first metallization layer power rail, the stitch may serve as a power rail spine for the first metallization layer power rail.

In one example, via-type connection 214 of FIG. 2 and second contact area jumper 215 may optionally be formed together, saving a mask versus forming them separately.

The construct of FIG. 2, splitting the contact area into a first contact area and a second contact area, is less complicated than the use of trench silicide can be over epitaxial semiconductor material. The second contact area is used as a local interconnect responsible for most of the connections to a first metallization level of an interconnect structure for semiconductor devices. A gate-open process with mask allows for a via-like connection to the gate. After the two-step contact area fill, a V₀ staple is used adjacent the second contact area to connect to V₀. In one example, a non-copper heavy metal having a minimum area less than that of copper (about 5,000 nm² even in sub-14 nm semiconductor technologies) may be used for the second contact area. For example, tungsten has a much smaller minimum area of about 1,500 nm², as well as better EM than copper. Along with a much smaller minimum area, tip-to-tip and tip-to-side spacing are also smaller. Thus, advantageously, V₀ need not connect at every contact-area-to-power-rail connection, allowing V₀ to stay at the spine, yet still achieve density. Line-end voids (MI overlap of V₀) for copper are relatively large, e.g., about 25-36 nm, whereas tungsten, for example, is about 12-18 nm. Moreover, the present invention enables a much more dense library of less than 7.5 tracks and/or considerable porosity for a second metallization layer above the first metallization layer. The unique three-dimensional connection between the first contact area, the second contact area and V₀ provides a robust and lower IR drop connection to the first metallization layer power rail. It also solves a conventional yield/reliability risk; that is, V₀ shorting to the trench silicide.

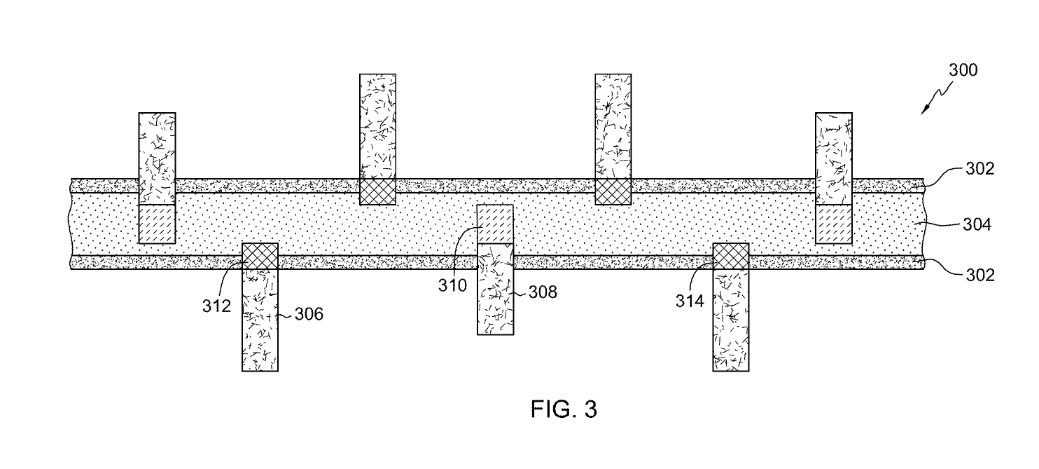

FIG. 3 is a top-down view of another example of a semiconductor structure 300, in accordance with one or more aspects of the present invention. The semiconductor structure includes, for example, a first metallization layer power rail 302 having a common first contact area 304 across a center thereof. Second contact areas (e.g., second contact areas 306 and 308) are situated orthogonal to the common first contact area and the power rail. Contacts (e.g., contacts 312 and 314) to a first metallization layer structure above the semiconductor structure (not shown) are adjacent to the second contact areas and over the common first contact area. V₀'s (e.g., V₀ 310) are situated with regularity or randomly, as shown here, along a center of the first metallization layer power rail and the first contact area.

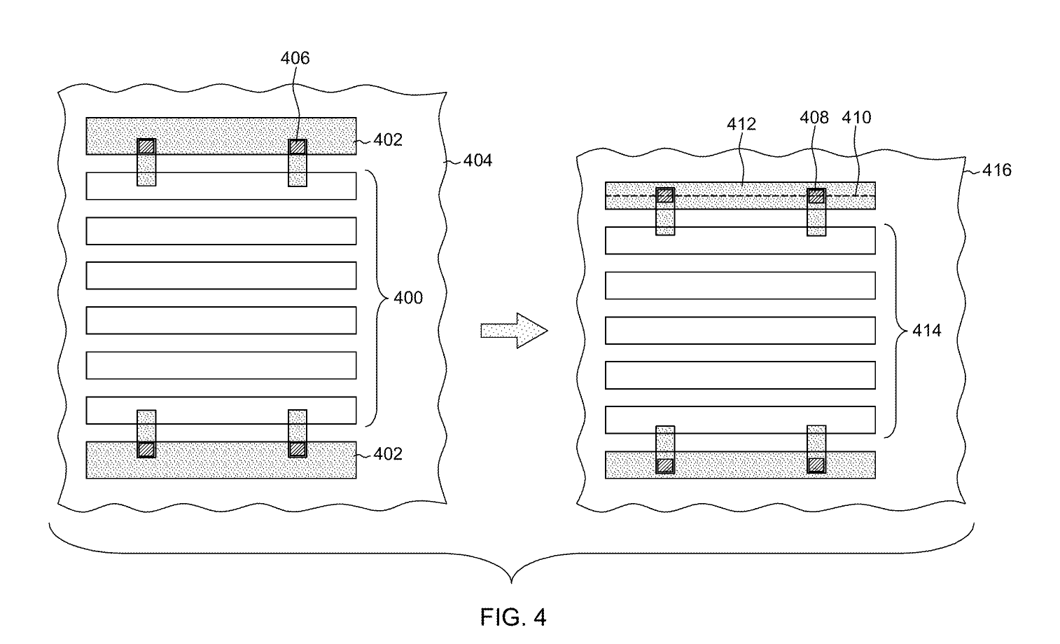

Using a CA-based spine allows for a reduction in width of a first metallization layer (M₁) power rail (see FIG. 4). For example, a CA-based spine of 30 nm width allows for a reduction in a width of a first metallization layer power rail from about 64 nm to about 40-50 nm. Placing V₀ at the center of the spine, together with the thinner, non-copper power rail allows for the use of single patterning (versus double or more patterning), enables scaling and allows for random placement of V₀ along a length of the spine, which is after the stage of use of a place-and-route (P&R) tool, and allows to meet EM/IR requirements. The CA-based spine further enables a smaller track library (below 7.5 tracks, or about 7% smaller) with regard to a conventional V₀/M₁-only power rail, or a significantly smaller library than a CB-based spine library.

FIG. 4 is one example of a top-down view showing the effect of centering V₀ on the power rail, in accordance with one or more aspects of the present invention. Tracks 400 and power rails 402 of a conventional interconnect structure 404 are shown on the left. Without centering V₀, for example, V₀ 406, along a center line of the power rails (copper) as in the present invention, a first number of tracks are needed (here, six are shown, but that is just an example). However, where V₀ (e.g., V₀ 408) is placed along a center line 410 of non-copper power rails (e.g., power rail 412), a reduced number of tracks 414 can be used (here five are shown) for interconnect structure 416.

As compared to conventional V₀ placement, centering V₀ together with a thinner non-copper power rail allows for the reduction in the number of tracks. The thinner power rail is enabled by the CA1-based spine that includes the stitch of FIG. 2. In one example, a thickness of a conventional power rail may be, for example, about 64 nm, while the power rail of the present invention may have a thickness of, for example, about 40 nm to about 50 nm.

In a first aspect, disclosed above is a semiconductor structure. The semiconductor structure includes source or drain region(s) of semiconductor device(s), a first metallization layer of an interconnect structure for the semiconductor device(s), first contact area(s) electrically coupled to the source or drain region(s), second contact area(s) electrically coupled to the first contact area(s), and V₀(s) electrically coupled to the second contact area(s), the first metallization layer being electrically coupled to the V₀(s). The semiconductor structure further includes first gate(s) and second gate(s), the first gate(s) and the second gate(s) are metal gates, the source or drain region(s) is situated adjacent one or more of the first gate(s) and the second gate(s), and the second contact area(s) is also electrically coupled to one or more of the first gate(s) and the second gate(s). Trench silicide is absent from the semiconductor structure, and the semiconductor structure is planar.

In one example, the first contact area(s) and the second contact area(s) are made of a non-copper heavy metal having a minimum area less than that of copper. In one example, the non-copper heavy metal may include, for example, tungsten and/or cobalt.

In a second aspect, disclosed above is a semiconductor structure. The semiconductor structure includes source or drain region(s) of semiconductor device(s), first contact area(s) electrically coupled to the source or drain region(s), second contact area(s) electrically coupled to the first contact area(s), V₀ bi directional staple(s) adjacent the second contact area(s) and electrically coupled to the second contact area(s) and the first contact area(s), V₀(s) above and electrically coupled to the second contact area(s) and the V₀ bi-directional staple(s). The semiconductor structure further includes first gate(s) and second gate(s), the first gate(s) and the second gate(s) are metal gates, the source or drain region(s) is situated adjacent one or more of the first gate(s) and the second gate(s), and the second contact area(s) is also electrically coupled to one or more of the first gate(s) and the second gate(s). Trench silicide is absent from the semiconductor structure, and the semiconductor structure is planar.

In one example, the source or drain region(s) may include, for example, epitaxial semiconductor material.

In one example, the semiconductor structure of the second aspect may further include, for example, a via-type gate contact electrically coupling the second contact area(s) and the one or more of the first gate(s) and the second gate(s). In one example, the semiconductor structure may further include, for example, a jumper from the second contact area(s) to the one or more of the first gate(s) and the second gate(s).

In one example, the semiconductor structure of the second aspect may further include, for example, a local interconnect, one or more of the V₀(s) being electrically coupled to the local interconnect.

In one example, the semiconductor structure of the second aspect may further include, for example, a first metallization layer power rail, and one or more of the V₀(s) is electrically coupled to the first metallization layer power rail. In one example, the first metallization layer power rail may be, for example, made of non-copper heavy metal having a minimum area less than that of copper. In one example, the non-copper heavy metal is made of tungsten and/or cobalt.

In one example, the V₀(s) may be, for example, situated along a center length of the first metallization layer power rail. In one example, the V₀(s) may include, for example, at least two V₀, the at least two V₀ being randomly electrically coupled to the first metallization layer power rail along a center length thereof.

In one example, the first contact area(s) and the second contact area(s) may be, for example, made of a non-copper heavy metal having a minimum area less than that of copper. In one example, the non-copper heavy metal may include, for example, tungsten and/or cobalt.

In a third aspect, disclosed above is a semiconductor structure. The semiconductor structure includes first contact area(s), second contact area(s) above and electrically coupled to the first contact area(s), V₀ bi-directional staple(s) adjacent the second contact area(s) and electrically coupled to the second contact area(s) and the first contact area(s). The semiconductor structure further includes V₀(s) above and electrically coupled to the second contact area(s) and the V₀ bi-directional staple(s), and a first metallization layer power rail electrically coupled to the V₀(s), the first metallization power rail being made of a non-copper heavy metal having a minimum area less than that of copper. The first contact area(s), the second contact area(s), the V₀ bi-directional staple(s) and the V₀(s), together with the first metallization layer power rail serve as a power rail spine.

In one example, the non-copper heavy metal may include, for example, tungsten and/or cobalt.

In one example, the V₀(s) of the semiconductor structure of the third aspect may be, for example, situated along a center length of the first metallization layer power rail.

In one example, the first contact area(s) and the second contact area(s) may be, for example, made of a non-copper heavy metal having a minimum area less than that of copper. In one example, the non-copper heavy metal may include, for example, tungsten and/or cobalt.

While several aspects of the present invention have been described and depicted herein, alternative aspects may be effected by those skilled in the art to accomplish the same objectives. Accordingly, it is intended by the appended claims to cover all such alternative aspects as fall within the true spirit and scope of the invention.

1. A semiconductor structure, comprising:
at least one source or drain region of at least one semiconductor device;
a first metallization layer of an interconnect structure for the at least one semiconductor device;
at least one first contact area electrically coupled to the at least one source or drain region;
at least one second contact area electrically coupled to the at least one first contact area;
at least one V₀ electrically coupled to the at least one second contact area, the first metallization layer being electrically coupled to the at least one V₀;
at least one first gate and at least one second gate, wherein the at least one first gate and the at least one second gate are metal gates, wherein the at least one source or drain region is situated adjacent one or more of the at least one first gate and the at least one second gate, and wherein the at least one second contact area is also electrically coupled to one or more of the at least one first gate and the at least one second gate; and
wherein a trench silicide is absent from the semiconductor structure, and wherein the semiconductor structure is planar.

2. The semiconductor structure of claim 1, wherein the at least one first contact area and the at least one second contact area are made of a non-copper metal.

3. The semiconductor structure of claim 2, wherein the non-copper metal comprises at least one of tungsten and cobalt.

4. A semiconductor structure, comprising:
at least one source or drain region of at least one semiconductor device;
at least one first contact area electrically coupled to the at least one source or drain region;
at least one second contact area electrically coupled to the at least one first contact area;
at least one V₀ bi-directional staple adjacent the at least one second contact area and electrically coupled to the at least one second contact area and the at least one first contact area;
at least one V₀ above and electrically coupled to the at least one second contact area and the at least one V₀ bi-directional staple;
at least one first gate and at least one second gate, wherein the at least one first gate and the at least one second gate are metal gates, wherein the at least one source or drain region is situated adjacent one or more of the at least one first gate and the at least one second gate, and wherein the at least one second contact area is also electrically coupled to one or more of the at least one first gate and the at least one second gate; and
wherein a trench silicide is absent from the semiconductor structure, and wherein the semiconductor structure is planar.

5. The semiconductor structure of claim 4, wherein the at least one source or drain region comprises epitaxial semiconductor material.

6. The semiconductor structure of claim 4, further comprising a via-type gate contact electrically coupling the one or more of the at least one first gate and the at least one second gate and the at least one second contact area.

7. The semiconductor structure of claim 6, further comprising a jumper from the at least one second contact area to the one or more of the at least one first gate and the at least one second gate.

8. The semiconductor structure of claim 4, further comprising a local interconnect, wherein one or more of the at least one V₀ is electrically coupled to the local interconnect.

9. The semiconductor structure of claim 4, further comprising a first metallization layer power rail, wherein one or more of the at least one V₀ is electrically coupled to the first metallization layer power rail.

10. The semiconductor structure of claim 9, wherein the first metallization layer power rail is made of non-copper metal.

11. The semiconductor structure of claim 10, wherein the non-copper metal comprises at least one of tungsten and cobalt.

12. The semiconductor structure of claim 10, wherein the at least one V₀ is situated along a center length of the power rail.

13. The semiconductor structure of claim 12, wherein the at least one V₀ comprises at least two V₀, the at least two V₀ being randomly electrically coupled to the first metallization layer power rail along a center length thereof.

14. The semiconductor structure of claim 4, wherein the at least one first contact area and the at least one second contact area are made of a non-copper metal.

15. The semiconductor structure of claim 14, wherein the non-copper metal comprises at least one of tungsten and cobalt.

16. A semiconductor structure, comprising:
at least one first contact area electrically coupled to an at least one source or drain region;
at least one second contact area above and electrically coupled to the at least one first contact area;
at least one V₀ bi-directional staple adjacent the at least one second contact area and electrically coupled to the at least one second contact area and the at least one first contact area;
at least one V₀ above and electrically coupled to the at least one second contact area and the at least one V₀ bi-directional staple;
a first metallization layer power rail electrically coupled to the at least one V₀, wherein the first metallization power rail is made of a non-copper metal;
at least one first gate and at least one second gate, wherein the at least one first gate and the at least one second gate are metal gates, wherein the at least one source or drain region is situated adjacent one or more of the at least one first gate and the at least one second gate, and wherein the at least one second contact area is also electrically coupled to one or more of the at least one first gate and the at least one second gate; and
wherein the at least one first contact area, the at least one second contact area, the at least one V₀ bi-directional staple and the at least one V₀, together with the first metallization layer power rail serve as a power rail spine.

17. The semiconductor structure of claim 16, wherein the non-copper metal comprises at least one of tungsten and cobalt.

18. The semiconductor structure of claim 16, wherein the at least one V₀ is situated along a center length of the power rail.

19. The semiconductor structure of claim 16, wherein the at least one first contact area and the at least one second contact area are made of a non-copper metal.

20. The semiconductor structure of claim 19, wherein the non-copper metal comprises at least one of tungsten and cobalt.
